(19) United States
(12) Patent Application Publication
(10) Pub. No.: US 2024/0414837 A1
(43) Pub. Date: Dec. 12, 2024

(54) COMPUTING APPARATUS AND HEAT DISSIPATION APPARATUS

(71) Applicant: BITMAIN TECHNOLOGIES INC., Beijing (CN)

(72) Inventors: Shitao TIAN, Beijing (CN); Yang LI, Beijing (CN); Te PI, Beijing (CN); Peng ZHAO, Beijing (CN); Zhihao ZHU, Beijing (CN); Haidie CHEN, Beijing (CN)

(21) Appl. No.: 18/741,541

(22) Filed: Jun. 12, 2024

(30) Foreign Application Priority Data
Jun. 12, 2023 (CN) 202321492979.X

(51) Int. Cl. H05K 1/02; H01L 23/367; H01L 23/373

(52) U.S. Cl. CPC H05K 1/0204; H05K 1/0209; H01L 23/3672; H01L 23/3736; H05K 2201/066

(57) ABSTRACT

The present application discloses a computing apparatus and a heat dissipation apparatus, where the computing apparatus includes: a circuit board, a first surface of which is provided with at least one computing unit; a first heat dissipation assembly, arranged on a second surface of the circuit board, the second surface being opposite to the first surface; and at least one second heat dissipation assembly, correspondingly arranged on a package of the at least one computing unit, respectively. Through the present application, a heat dissipation efficiency of the computing apparatus can be improved.

### CROSS-REFERENCE TO RELATED APPLICATION

The present application claims priority to Chinese Patent Application No. 202321492979X, filed on Jun. 12, 2023, which is hereby incorporated by reference in its entirety.

### TECHNICAL FIELD

The present application relates to the technical field of electronic devices, in particular to a computing apparatus and a heat dissipation apparatus.

### BACKGROUND

With the development of semiconductor technology, high-density and high-power devices have become a mainstream. A common means is to set a series structure of multiple processing chips on a circuit board to construct a computing board, and assemble multiple computing boards into a high-performance computing device. This chip arrangement can greatly improve the computing processing capacity of the device, but due to a high integration density of the chips, will generate a large amount of heat when running, so it is necessary to arrange a heat sink at the chips' positions to dissipate heat generated by the chips.

At present, a common installation method of a heat sink on a front surface of a circuit board is to install a monolithic heat sink on the whole circuit board, so as to realize heat dissipation and cooling of all chips. Due to a machining tolerance of the heat sink and a difference in height of the chips, the monolithic heat sink will have a poor contact with some chips and there will also be a great thickness difference in heat conduction grease filled between the heat sink and the chips, which on one hand makes an overall temperature uniformity characteristic of the chips deteriorated and a heat dissipation efficiency reduced, and on the other hand may cause extrusion to some chips higher than others so that these chips will be damaged due to an excessive pressure.

### SUMMARY

The present application provides a computing apparatus and a heat dissipation apparatus, which can improve the heat dissipation efficiency of the computing device.

In a first aspect, the present application provides a computing apparatus, including: a circuit board, provided with at least one computing unit on a first surface thereof; a first heat dissipation assembly, arranged on a second surface of the circuit board, the second surface being opposite to the first surface; and at least one second heat dissipation assembly, correspondingly arranged on a package of the at least one computing unit, respectively.

In some possible implementations, the circuit board is an aluminum substrate.

In some possible implementations, the package of each computing unit in the at least one computing unit is provided with a metal plating layer, and each second heat dissipation assembly is welded to the metal plating layer.

In some possible implementations, a plurality of heat dissipation fins are arranged in parallel on the second heat dissipation assembly.

In some possible implementations, a plurality of groups of the second heat dissipation assemblies are provided; a height of each group of the second heat dissipation assemblies and/or a length of each group of the second heat dissipation assemblies gradually increases along an airflow direction.

In some possible implementations, when the at least one second heat dissipation assembly are a plurality of second heat dissipation assemblies, the plurality of second heat dissipation assemblies are arranged at intervals, and a gap between adjacent second heat dissipation assemblies in the plurality of second heat dissipation assemblies form an airflow channel; a gas flows through the plurality of second heat dissipation assemblies by the airflow channel.

In some possible implementations, the computing apparatus further includes a connection element, and the first heat dissipation assembly is detachably connected with the circuit board through the connection element.

In some possible implementations, a heat conduction material is filled between the first heat dissipation assembly and the second surface, and the heat conduction material is configured to seal a gap between the first heat dissipation assembly and the circuit board.

In some possible implementations, the computing apparatus further includes a gas inlet assembly and a gas outlet assembly, wherein the gas inlet assembly is arranged at one side of the first heat dissipation assembly and/or the at least one second heat dissipation assembly, and the gas outlet assembly is arranged at the other side of the first heat dissipation assembly and/or the at least one second heat dissipation assembly; where the gas inlet assembly is configured to convey a gas to the first heat dissipation assembly and/or the at least one second heat dissipation assembly, and the gas outlet assembly is configured to output the gas that has flowed through the first heat dissipation assembly and/or the at least one second heat dissipation assembly.

In a second aspect, the present application provides a heat dissipation apparatus, including the first heat dissipation assembly and the at least one second heat dissipation assembly in the computing apparatus according to the first aspect, where the first heat dissipation assembly and the at least one second heat dissipation assembly are configured to dissipate heat generated when the at least one computing unit is working.

Compared with the prior art, the technical solutions provided by the present application has the beneficial effects as follows.

In the present application, each computing unit on the first surface of the circuit board dissipates heat through one second heat dissipation assembly, and the second surface of the circuit board dissipates heat through the first heat dissipation assembly. In this way, a heat dissipation effect is improved through such double-sided heat dissipation, and each computing unit dissipates heat through a separate second heat dissipation assembly so that the computing unit can be fully attached to the second heat dissipation assembly, which further improves the heat dissipation effect and at the same time avoids a situation where damage to the computing unit due to extrusion in the case of a monolithic heat dissipation assembly.

It should be understood that both the foregoing general description and the following detailed description are exemplary and explanatory only and are not used to limit the present application.

### BRIEF DESCRIPTION OF DRAWINGS

The accompanying drawings, which are incorporated in and constitute a part of the present specification, illustrate embodiments consistent with the present application and serve to, together with the specification, explain the principles of the present application.

FIG. 1 is a schematic structural diagram of a computing apparatus in an embodiment of the present application.

FIG. 2 is a schematic structural diagram of a second heat dissipation assembly in an embodiment of the present application.

FIG. 3 is another schematic structural diagram of a second heat dissipation assembly in an embodiment of the present application.

FIG. 4 is a top view of a second heat dissipation assembly in an embodiment of the present application.

FIG. 5 is a schematic structural diagram when there are a plurality of groups of second heat dissipation assemblies in an embodiment of the present application.

FIG. 6a is a front view of another schematic structure of a computing apparatus in an embodiment of the present application.

FIG. 6b is a top view of another schematic structure of a computing apparatus in an embodiment of the present application.

FIG. 6c is a side view of another schematic structure of a computing apparatus in an embodiment of the present application.

FIG. 7 is another schematic structural diagram of a computing apparatus in an embodiment of the present application.

FIG. 8 is a schematic structural diagram of a power supply assembly in an embodiment of the present application.

FIG. 9 is another schematic structural diagram of a computing apparatus in an embodiment of the present application.

FIG. 10 is another schematic structural diagram of a computing apparatus in an embodiment of the present application.

### DESCRIPTION OF THE REFERENCE NUMBERS

10. computing apparatus; 11. circuit board; 12. first heat dissipation assembly; 13. second heat dissipation assembly; a1. first surface; a2. second surface; 111. computing unit; 21. heat dissipation fin; 22. heat conduction surface; 31. heat dissipation fin; 32. heat conduction metal tube; 321. heat conduction surface; 60. connection element; 61. nut; 62. screw; 63. gap; 71. first welding layer; 72. metal plating; 73. second welding layer; 74. heat conduction layer; 80. power supply assembly; 81. positive electrode unit; 82. negative electrode unit; 90. connection assembly; 101. gas inlet assembly; 102. gas outlet assembly.

### DESCRIPTION OF EMBODIMENTS

Exemplary embodiments, which are illustrated in the accompanying drawings, will be described in detail. When the following description refers to the drawings, unless otherwise indicated, the same numerals in different drawings indicate the same or similar elements. The following exemplary embodiments do not represent all embodiments of the present application. Rather, they are merely examples of apparatuses of some aspects of the present application as defined in the appended claims.

Other embodiments of the present application will easily occur to those skilled in the art after considering the specification and practicing the application applied for herein. The present application is intended to cover any variations, uses or adaptive changes of the present application, and these variations, uses or adaptive changes follow the general principles of the present application and include common sense or common technical means in the technical field of the present application. The specification and examples are to be regarded as exemplary only, and true scope and spirit of the present application is as defined in the claims.

In order to explain the technical solutions of the present application, the following will be described with reference to specific embodiments.

With the development of semiconductor technology, high-density and high-power devices have become a mainstream, especially in the field of artificial intelligence and big data integrated computing. A common means is to set a series structure of multiple processing chips on a circuit board to construct a computing board, and assemble multiple computing boards into a high-performance computing device.

This chip arrangement can greatly improve the computing processing capacity of the device, but due to a high integration density of the chips, the chips will generate a large amount of heat when running. If the generated heat cannot be dissipated in time, it will cause damage to semiconductor chips, so it is necessary to arrange a heat dissipation fin at the chips' positions to dissipate the heat generated by the chips.

At present, a common installation method of a heat sink on a front surface of a circuit board is to install a monolithic heat sink on the whole circuit board, and make the heat sink contact with all chips on the circuit board through elastic pressing elements so as to realize heat dissipation and cooling of all chips. Due to a machining tolerance of the heat sink and a difference in height of the chips, the monolithic heat sink will have a poor contact with some chips and there will also be a great thickness difference in heat conduction grease filled between the heat sink and the chips, which on one hand makes an overall temperature uniformity characteristic of the chips deteriorated, and on the other hand may cause extrusion to some chips higher than others so that these chips will be damaged due to an excessive pressure.

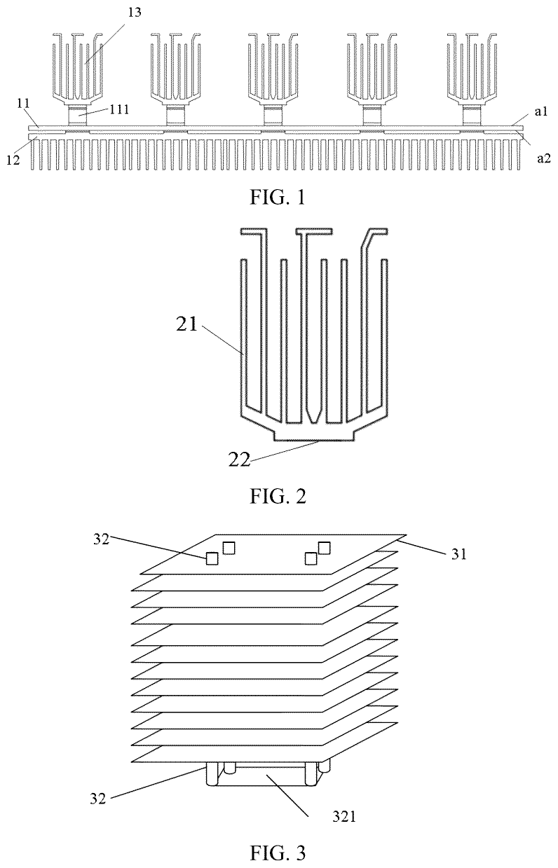

In order to solve the above problems, an embodiment of the present application provides a computing apparatus. FIG. 1 is a schematic structural diagram of a computing apparatus in an embodiment of the present application. Referring to FIG. 1, the computing apparatus 10 includes a circuit board 11, a first heat dissipation assembly 12 and at least one second heat dissipation assembly 13. A first surface a1 of the circuit board 11 is provided with at least one computing unit 111. The first heat dissipation assembly 12 is disposed on a second surface a2 of the circuit board 11, the second surface a2 is opposite to the first surface a1. The at least one second heat dissipation assembly 13 is correspondingly arranged on a package of the at least one computing unit 111, respectively.

It should be noted that the circuit board 11 has a circuit for realizing a predetermined function. The circuit on the circuit board 11 can be made by any circuit board manufacturing process, for example, etching method, pre-coating photosensitive copper plate method, etc. The circuit board 11 can be used as a carrier of the computing unit 111, providing electrical connection and/or insulation between computing units 111 arranged on the circuit board 11, and the computing units 111 can be connected and fixed by the circuit board 11 to form an electronic circuit for realizing a specific function.

The computing unit 111 can be an electronic component with a computing function arranged on the circuit board 11. For example, the computing unit 111 can be a

Central Processing Unit (CPU), a Graphics Processing Unit (GPU), a Microcontroller Unit (MCU) and the like. When the number of the at least one computing unit 111 is plural, each computing unit 111 may be the same electronic component or different electronic components. For example, one circuit board 11 may be provided with a plurality of identical CPUs at the same time, or one circuit board 11 may be provided with a CPU, a GPU and the like, respectively.

Furthermore, the package of the computing unit 111 can be a housing for wrapping the computing unit 111, and the housing plays the role of placing, fixing, sealing, protecting the computing unit 111 and enhancing the heat dissipation performance of the computing unit 111. At the same time, the housing can also be a bridge for communicating between the computing unit 111 and an external circuit. The contacts on the computing unit 111 are connected to a plurality of pins corresponding to the package housing through wires, and these pins are connected with the circuit board 11 through corresponding interfaces on the circuit board 11. Alternatively, the contact on the computing unit 111 can also be connected to a plurality of interfaces corresponding to the package housing through wires, and these interfaces can be connected with the circuit board 11 through a plurality of corresponding pins on the circuit board 11.

In some embodiments, the first heat dissipation assembly 12 and the second heat dissipation assembly 13 can be any type of radiator, for example, water-cooled radiator, air-cooled radiator, etc. The first heat dissipation assembly 12 and the second heat dissipation assembly 13 may have the same or different types, as long as it is ensured that each second heat dissipation assembly 13 dissipates heat for a corresponding computing unit 111 and the first heat dissipation assembly 12 dissipates heat for the second surface a2 of an entire circuit board 11. The types of the first heat dissipation assembly 12 and the second heat dissipation assembly 13 are not limited in embodiments of the present application.

In some embodiments, in order to improve the heat dissipation efficiency so that the first heat dissipation assembly 12 and the second heat dissipation assembly 13 can quickly absorb heat and transfer the heat to an external environment, the first heat dissipation assembly 12 and the second heat dissipation assembly 13 can be made of a metal or metal alloy material with good heat conduction performance, such as aluminum, copper, aluminum alloy or copper alloy.

In an embodiment of the present application, each computing unit 111 on the first surface a1 of the circuit board 11 dissipates heat through one second heat dissipation assembly 13, and the second surface a2 of the circuit board 11 dissipates heat through the first heat dissipation assembly 12. In this way, the heat dissipation effect is improved through such double-sided heat dissipation, each computing unit 111 dissipates heat through a separate second heat dissipation assembly 13, so that the computing unit 111 can be fully attached to the second heat dissipation assembly 13, the heat dissipation effect is further improved, and at the same time, a situation where damage to the computing unit 111 due to extrusion in the case of a monolithic heat dissipation assembly is avoided.

In some embodiments, the computing unit 111 may be fixedly arranged on the circuit board 11, or the computing unit 111 may be detachably arranged on the circuit board 11. For example, when the computing unit 111 is fixedly arranged on the circuit board 11, a pin on the computing unit 111 can be fixed to a contact on the circuit board 11 by metal welding. Alternatively, when the computing unit 111 is detachably arranged on the circuit board 11, the pin on the computing unit 111 can be arranged in contact with the contact on the circuit board 11, and the computing unit 111 can be fixed on the circuit board 11 through an externally provided detachable fixing bracket.

In some possible implementations, the circuit board 11 may be an aluminum substrate.

Understandably, at present, most of circuit boards use a FR4 material, which has good thermal stability and excellent insulation performance, and is not prone to buckling and deformation when passing through a furnace at high temperature. However, FR4 material is an anisotropic material, and has a low thermal conductivity in a direction perpendicular to a surface of the board. The bad thermal conductivity is not conducive to the heat generated by the chip to be guided to the heat dissipation assembly on the back surface of the circuit board. In a case of high heat dissipation requirement, the circuit board using FR4 material cannot meet the requirement. In an embodiment of the present application, the circuit board 11 uses an aluminum substrate material, which can improve the heat dissipation efficiency of the heat dissipation assembly on the back surface of the circuit board 11 based on the excellent temperature uniformity characteristic of the aluminum substrate.

In some possible embodiments, a plurality of heat dissipation fins may be arranged in parallel on the second heat dissipation assembly 13.

It can be understood that taking the second heat dissipation assembly 13 as a radiator as an example, a working principle of using the radiator to dissipate the heat generated by the computing unit 111 is that: the radiator is brought into contact with a surface of the computing unit 111, so that the radiator can absorb heat generated by the computing unit 111, and then the radiator transfers the heat to an external environment. In order to enable the radiator to quickly transfer the heat to the external environment after absorbing the heat, it is possible to increase a heat dissipation area of the radiator.

Exemplarily, FIG. 2 is a schematic structural diagram of the second heat dissipation assembly 13 in an embodiment of the present application. Referring to FIG. 2, a plurality of heat dissipation fins 21 are arranged in parallel on the second heat dissipation assembly 13, and the plurality of heat dissipation fins 21 are fixed on a heat conduction surface 22 of the second heat dissipation assembly 13. The heat conduction surface 22 is used to contact with the computing unit 111, thereby absorbing the heat generated by the computing unit 111.

It should be noted that, based on an actual application requirement, the second heat dissipation assembly 13 may not be limited to such parallel-arranged structure of the heat dissipation fins 21 as shown in the above-mentioned FIG. 2, and the plurality of heat dissipation fins 21 may also be designed in various regular or irregular shapes to increase the heat dissipation area, thus helping the computing unit 111 to dissipate heat faster and better.

Exemplarily, FIG. 3 is another schematic structural diagram of the second heat dissipation assembly 13 in an embodiment of the present application. Referring to FIG. 3, a plurality of heat dissipation fins 31 are arranged in parallel on the second heat dissipation assembly 13, and the plurality of heat dissipation fins 31 are fixed together by a heat conduction metal tube 32. Where, there is a heat conduction surface 321 on the heat conduction metal tube 32, and the heat conduction surface 321 is configured to contact with the computing unit 111, so as to absorb the heat generated by the computing unit 111.

In some possible embodiments, the package of each of the at least one computing unit 111 is provided with a metal plating layer, and each second heat dissipation assembly 13 is welded to the metal plating layer.

It can be understood that, taking the second heat dissipation assembly 13 as a radiator as an example, the radiator is usually made of a metal or metal alloy material, and a common material for the package of the computing unit 111 can be plastic, ceramic, glass, etc. By providing the metal plating layer on the computing unit 111, the second heat dissipation assembly 13 can be better welded to the package of the computing unit 111. At the same time, setting a metal plating layer on the computing unit 111 can also provide a certain shielding effect to prevent an external radiation interference sources from affecting the computing unit 111.

In some embodiments, the metal plating layer can be a plating layer of any type of metal material, for example, the metal plating layer can be copper metal plating layer, silver metal plating layer, gold metal plating layer and the like.

In some embodiments, in order to avoid a damage to the computing unit 111 due to a high temperature, a welding material for welding between the second heat dissipation assembly 13 and the metal plating layer may be a material with a low melting point. For example, the welding material can be solder paste, tin wire, etc.

In some embodiments, the second heat dissipation assembly 13 is fixed on the package of the computing unit 111, which can be fixed through an additional fixing structure. In other embodiments, the second heat dissipation assembly 13 can be fixed on the package of the computing unit 111 through bonding via a heat conduction adhesive.

In some possible embodiments, when the at least one second heat dissipation assembly 13 are a plurality of second heat dissipation assemblies 13, the plurality of second heat dissipation assemblies 13 are arranged at intervals, and a gap between adjacent second heat dissipation assemblies 13 in the plurality of second heat dissipation assemblies 13 form an airflow channel; a gas flows through the plurality of second heat dissipation assemblies 13 by the airflow channel.

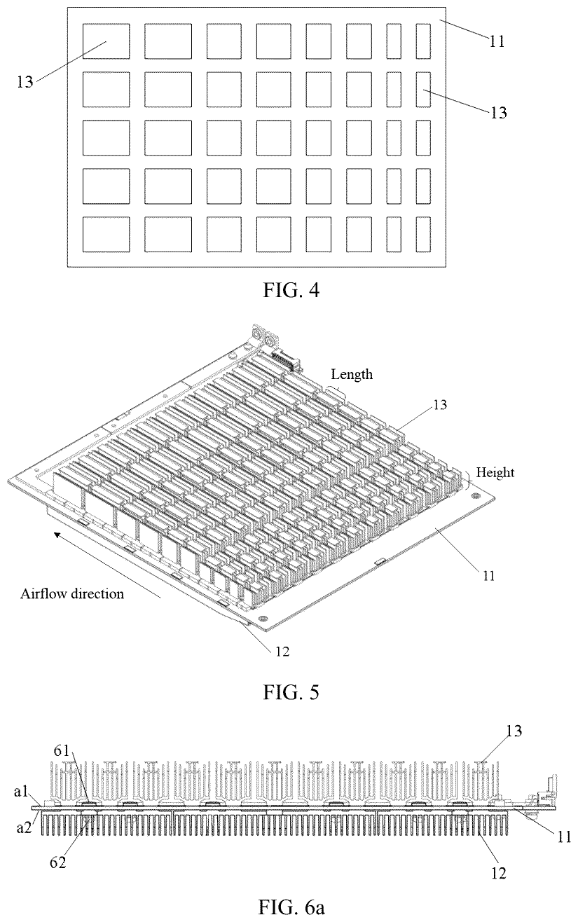

Exemplarily, FIG. 4 is a top view of the second heat dissipation assembly 13 in an embodiment of the present application. Referring to FIG. 4, there is a gap between adjacent second heat dissipation assemblies 13, and the gap forms an airflow channel through which a gas can flow. After absorbing the heat of the computing unit 111, the second heat dissipation assembly 13 transfers the absorbed heat to the external environment through the heat dissipation fins. The gas flowing through the second heat dissipation assembly 13 can be heated by the heat dissipation fins, so that the heat on the heat dissipation fins is taken away, the temperature of the second heat dissipation assembly 13 is reduced, and thus the heat dissipation effect is achieved.

In some embodiments, in order to quickly take away the heat of the second heat dissipation assembly 13, the gas flowing through the second heat dissipation assembly 13 may be a gas with high specific heat capacity, such as air, carbon dioxide, helium and the like.

In some possible embodiments, the second heat dissipation assemblies 13 are provided with a plurality of groups, and a height and/or a length of each group of second heat dissipation assemblies 13 gradually increases along an airflow direction.

Understandably, taking the heat dissipation assembly 13 as a radiator as an example, after absorbing heat, the radiator transfers the heat to the external environment, which will lead to an increase in temperature of an air around the radiator. When the temperature-increased air flows along the airflow direction, the second heat dissipation assemblies 13 in the airflow direction will be heated by the temperature-increased air, resulting in higher and higher temperature of the second heat dissipation assemblies 13 in the airflow direction. Therefore, in order to accelerate the heat dissipation of the second heat dissipation assembly 13 in the airflow direction and ensure a uniform temperature of the computing apparatus 10 as a whole, a size of the second heat dissipation assembly 13 in the airflow direction can be gradually increased, thereby increasing a heat dissipation area of the second heat dissipation assembly 13, realizing a rapid cooling of the second heat dissipation assembly 13 and improving the heat dissipation efficiency.

In some embodiments, increase of the height and/or length of the second heat dissipation assembly 13 may be realized by increasing the size and/or the number of the heat dissipation fins in the second heat dissipation assembly 13.

Exemplarily, FIG. 5 is a schematic structural diagram when there are a plurality of groups of second heat dissipation assemblies 13 in an embodiment of the present application. Referring to FIG. 5, a height of the second heat dissipation assemblies 13 and a length of the second heat dissipation assemblies 13 gradually increase along the airflow direction.

In some possible embodiments, still referring to FIG. 5, the computing apparatus 10 may further include a connection element, and the first heat dissipation assembly 12 is detachably connected with the circuit board 11 through the connection element.

The connection element can be any structure that can connect the first heat dissipation assembly 12 and the circuit board 11 together. For example, the connection element can be a bolt structure, a snap structure, etc.

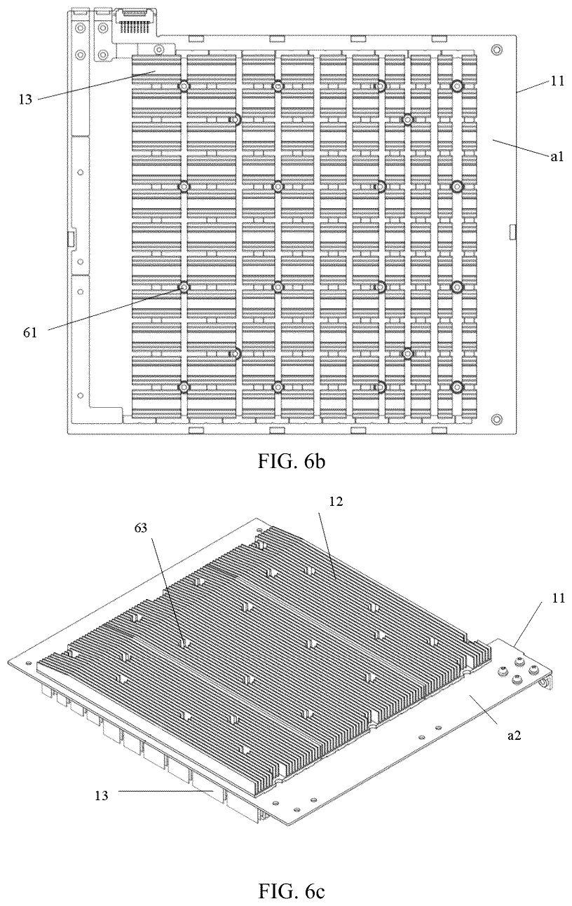

Exemplarily, taking the connection element as a bolt structure as an example, FIG. 6 shows a schematic structural diagram of a computing apparatus 10 in an embodiment of the present application. FIG. 6a is a front view of another schematic structure of the computing apparatus 10 in an embodiment of the present application. Referring to FIG. 6a, the connection element 60 includes a nut 61 and a screw 62, where the nut 61 is arranged on the first surface a1 of the circuit board 11, and the screw 62 can be connected with the nut 61 after passing through the first heat dissipation assembly 12 and the circuit board 11, so as to fix the first heat dissipation assembly 12 to the second surface a2 of the circuit board 11. FIG. 6b is a top view of another schematic structure of the computing apparatus 10 in an embodiment of the present application. Referring to FIG. 6b, a plurality of nuts 61 are arranged on the first surface a1 of the circuit board 11. The nuts 61 are arranged in gaps between the second heat dissipation assemblies 13.

FIG. 6c is a side view of another schematic structure of the computing apparatus 10 in an embodiment of the present application. Referring to FIG. 6c, there are a plurality of gaps 63 in the first heat dissipation assembly 12, and the screws 62 can pass through the gaps 63 and pass through the circuit board 11 to be connected with the nuts 61.

It should be noted that since the circuit board is provided with an electronic circuit, in order to prevent the nut 61 arranged on the circuit board 11 from damaging the circuit board 11 due to an over-tight locking degree of the bolt structure, an insulation spacer can also be arranged between the circuit board 11 and the nut 61.

In some possible embodiments, a heat conduction material is filled between the first heat dissipation assembly 12 and the second surface a2, and the heat conduction material is used to seal the gap between the first heat dissipation assembly 12 and the circuit board 11.

It can be understood that when the second surface a2 of the circuit board 11 is connected with the first heat dissipation assembly 12, there may be a gap between contact surfaces of the them because they are not exactly parallel. As a result, the second surface a2 of the circuit board 11 and the first heat dissipation assembly 12 cannot be in full contact with each other, and has a relatively small contact area, which leads to a low transfer rate of heat from the second surface a2 to the first heat dissipation assembly 12 and affects the heat dissipation efficiency. In an embodiment of the present application, the gap between the first heat dissipation assembly 12 and the circuit board 11 is sealed by filling the heat conduction material between the first heat dissipation assembly 12 and the second surface a2, so that the contact area between the first heat dissipation assembly 12 and the circuit board 11 is increased, and the heat dissipation efficiency can be improved.

In some embodiments, in order to avoid frequent replacement of the heat conduction material, the heat conduction material can be selected from a material with a low evaporation loss characteristic. For example, the heat conduction material can be a liquid heat conduction silicone grease, liquid gold, etc.

The computing apparatus 10 provided by the present application will be described with reference to specific embodiments. FIG. 7 is another schematic structural diagram of a computing apparatus 10 in an embodiment of the present application. Referring to FIG. 7, a computing unit 111 is arranged on the first surface a1 of the circuit board 11, and the computing unit 111 and the circuit board 11 are fixed together by a first welding layer 71. The package of the computing unit 111 has a metal plating layer 72, and the second heat dissipation assembly 13 and the metal plating layer 72 are fixed together by a second welding layer 73. The first heat dissipation assembly 12 is connected to the second surface a2 of the circuit board, and a heat conduction layer 74 formed by a heat conduction material is filled between the first heat dissipation assembly 12 and the second surface a2 of the circuit board.

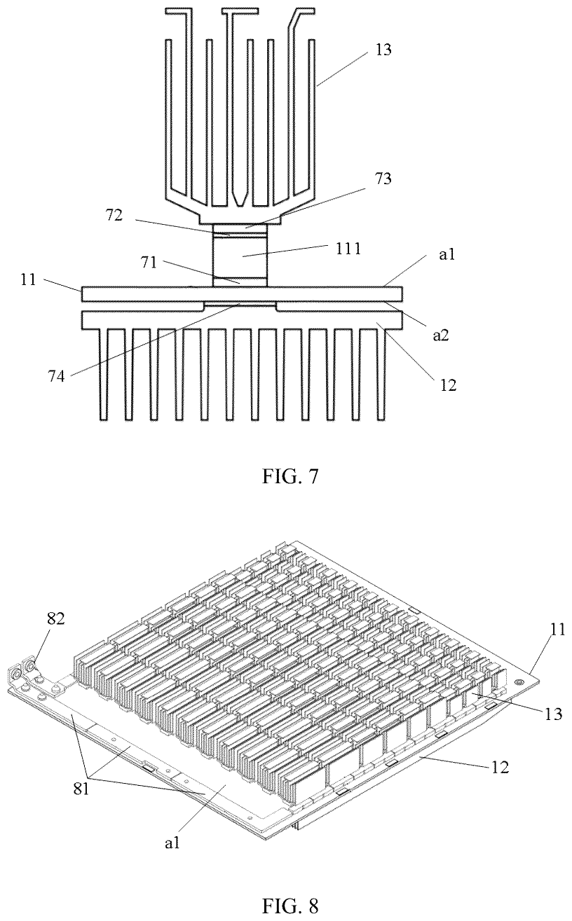

In some embodiments, the computing apparatus 10 further includes a power supply assembly for supplying power to the computing unit 111 disposed on the circuit board 11. FIG. 8 is a schematic structural diagram of a power supply assembly 80 in an embodiment of the present application. Referring to FIG. 8, the power supply assembly 80 includes a positive electrode unit 81 and a negative electrode unit 82, both of which are disposed on the first surface a1 of the circuit board 11.

Exemplarily, the positive electrode unit 81 and the negative electrode unit 82 are formed by a conductive metal or nonmetallic material, such as copper, gold, graphite, and the like.

In some embodiments, in a circuit arranged on the circuit board 11, there is a circuit structure that connects the power supply assembly 80 with each computing unit 111 arranged on the circuit board 11. The power supply assembly 80 supplies power to the computing unit 111 through the circuit in the circuit board 11.

In some embodiments, the positive electrode unit 81 and the negative electrode unit 82 may be electronic components embedded in the circuit board 11, or the positive electrode unit 81 and the negative electrode unit 82 may be fixed on the circuit board 11 through a fixing structure.

Exemplarily, the fixing structure may be a plurality of bolt structures, which are distributed at different positions of the positive electrode unit 81 and the negative electrode unit 82 to fix the positive electrode unit 81 and the negative electrode unit 82 to the circuit board 11. Alternatively, the fixing structure may be a plurality of snap structures, which are distributed at different positions of edges of the positive electrode unit 81 and the negative electrode unit 82. When the snap structures are closed, the positive electrode unit 81 and the negative electrode unit 82 are fixed on the circuit board 11. Alternatively, the fixing structure can be an adhesive glue, and the positive electrode unit 81 and the negative electrode unit 82 are connected to the circuit board 11 by the adhesive glue.

In some embodiments, the computing apparatus 10 may further include a connection assembly, which is used as a port for input and output of a signal of the computing apparatus 10.

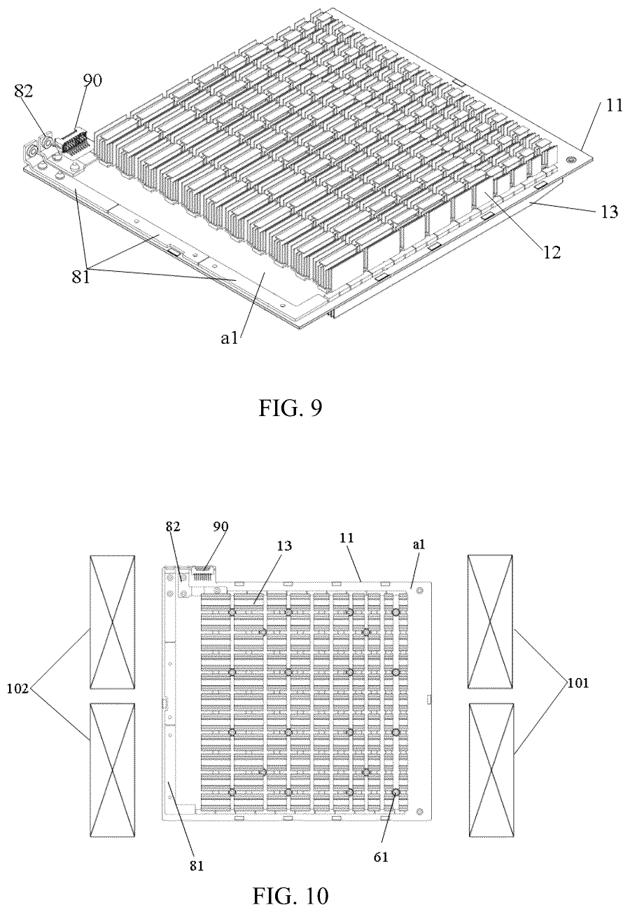

Exemplarily, FIG. 9 is another schematic structural diagram of a computing apparatus 10 in an embodiment of the present application. Referring to FIG. 9, the connection assembly 90 is arranged on the circuit board 11 and used as a signal input and output port for information interaction with other device.

It can be understood that the connection assembly 90 serves as a port for input and output of a signal, and the type of the port may not be limited to the structural type shown in the above-mentioned FIG. 9, and may also be selected on its own based on an actual requirement. For example, the connection assembly 90 can be a Universal Serial Bus (USB), a High-Definition Digital Display Port (DP), and the like. Alternatively, the input and output of a signal are realized by wireless signal transmission, in which case, the connection assembly 90 can also be a wireless signal transmission module integrated in the circuit board 11, for example, wireless fidelity (Wi-Fi), Bluetooth, etc.

In some possible embodiments, the computing apparatus 10 further includes a gas inlet assembly and a gas outlet assembly, where the gas inlet assembly is arranged at one side of the first heat dissipation assembly and/or the at least one second heat dissipation assembly, and the gas outlet assembly is arranged at the other side of the first heat dissipation assembly and/or the at least one second heat dissipation assembly; where the gas inlet assembly is used for conveying gas to the first heat dissipation assembly and/or the at least one second heat dissipation assembly, and the gas outlet assembly is used for outputting the gas that has flowed through the first heat dissipation assembly and/or the at least one second heat dissipation assembly.

Exemplarily, FIG. 10 is another schematic structural diagram of a computing apparatus 10 in an embodiment of the present application. Referring to FIG. 10, both the number of the gas inlet assembly 101 and the number of the gas outlet assembly 102 are two, and the gas inlet assemblies 101 and the gas outlet assemblies 102 are respectively arranged at two ends of the circuit board 11.

Exemplarily, taking the gas flowing through the computing apparatus 10 as air as an example, the gas inlet assembly 101 blows air towards the computing apparatus 10, which can speed up the air flow rate in the computing apparatus 10 and drive the heat in the computing apparatus 10 to be output from the gas outlet assembly 102. The gas outlet assembly 102 can output the air in the computing apparatus 10 from the computing apparatus 10 to the external environment, thereby accelerating the heat dissipation of the computing apparatus 10.

In some embodiments, the gas inlet assembly and the gas outlet assembly may be the same type of fan structure.

Understandably, when one end of the fan structure blows air, a negative pressure environment is formed on a back side of a blowing direction due to air convection, so that air on the back side of the blowing direction can be extracted. Therefore, when the gas inlet assembly and the gas outlet assembly are of the same type of fan structure, it is only necessary to let the blowing direction of the gas inlet assembly face a back side of a blowing direction of the gas outlet assembly. In this way, the gas inlet assembly blows air towards the computing apparatus 10, which can speed up the air flow rate in the computing apparatus 10. At the same time, an air extraction effect of the gas outlet assembly can also speed up the air output from the computing apparatus 10, which can improve the heat dissipation efficiency of the computing apparatus 10.

In the present embodiment, each computing unit 111 on the first surface a1 of the circuit board 11 dissipates heat through a second heat dissipation assembly 13, and the second surface a2 of the circuit board 11 dissipates heat through the first heat dissipation assembly 12. In this way, the heat dissipation effect is improved through such double-sided heat dissipation, and each computing unit 111 dissipates heat through the separate second heat dissipation assembly 13, so that the computing unit 111 can be fully attached to the second heat dissipation assembly 13, and the heat dissipation effect is further improved, and at the same time, the situation where damage to the computing unit 111 due to extrusion in the case of a monolithic heat dissipation assembly is avoided.

Based on the same concept, an embodiment of the present application provides a heat dissipation apparatus, which may include a first heat dissipation assembly 12 and at least one second heat dissipation assembly 13 in the computing apparatus 10 described in one or more embodiments above.

The first heat dissipation assembly 12 and the at least one second heat dissipation assembly 13 are used to dissipate heat generated when at least one computing unit 111 is working.

In the present embodiment, each computing unit 111 on the first surface a1 of the circuit board 11 dissipates heat through one second heat dissipation assembly 13, and the second surface a2 of the circuit board 11 dissipates heat through the first heat dissipation assembly 12. In this way, the heat dissipation effect is improved through such double-sided heat dissipation, and each computing unit 111 dissipates heat through a separate second heat dissipation assembly 13, so that the computing unit 111 can be fully attached to the second heat dissipation assembly 13, and the heat dissipation effect is further improved, and at the same time, a situation where damage to the computing unit 111 due to extrusion in the case of a monolithic heat dissipation assembly is avoided.

It can be understood by those skilled in the art that the sequence number of each step in the above-mentioned embodiments does not mean an order of execution, and the order of execution of each process should be determined according to its function and internal logic, and should not constitute any limitation on the implementation process of the embodiments of the present application.

The above-mentioned embodiments are only used to illustrate the technical solutions of the present application, but are not to limit them. Although the present application has been described in detail with reference to the foregoing embodiments, it should be understood by those skilled in the art that the technical solutions described in the foregoing embodiments can still be modified or some technical features therein can be replaced by equivalents. However, these modifications or replacements do not make the essence of the corresponding technical solutions deviate from the spirit and scope of the technical solutions of the embodiments of the present application, and shall fall into the protection scope of the present application.

What is claimed is:

1. A computing apparatus, comprising:
a circuit board, provided with at least one computing unit on a first surface thereof;
a first heat dissipation assembly, arranged on a second surface of the circuit board, the second surface being opposite to the first surface; and
at least one second heat dissipation assembly, correspondingly arranged on a package of the at least one computing unit, respectively.

2. The computing apparatus according to claim 1, wherein the circuit board is an aluminum substrate.

3. The computing apparatus according to claim 1, wherein the package of each computing unit in the at least one computing unit is provided with a metal plating layer, and each second heat dissipation assembly is welded to the metal plating layer.

4. The computing apparatus according to claim 1, wherein a plurality of heat dissipation fins are arranged in parallel on the second heat dissipation assembly.

5. The computing apparatus according to claim 4, wherein the circuit board is an aluminum substrate.

6. The computing apparatus according to claim 4, wherein the package of each computing unit in the at least one computing unit is provided with a metal plating layer, and each second heat dissipation assembly is welded to the metal plating layer.

7. The computing apparatus according to claim 4, wherein a plurality of groups of second heat dissipation assemblies are provided; a height of each group of second heat dissipation assemblies gradually increases along an airflow direction; and/or a length of each group of second heat dissipation assemblies gradually increase along the airflow direction.

8. The computing apparatus according to claim 7, wherein the circuit board is an aluminum substrate.

9. The computing apparatus according to claim 7, wherein the package of each computing unit in the at least one computing unit is provided with a metal plating layer, and each second heat dissipation assembly is welded to the metal plating layer.

10. The computing apparatus according to claim 1, wherein when the at least one second heat dissipation assembly are a plurality of second heat dissipation assemblies, the plurality of second heat dissipation assemblies are arranged at intervals, and a gap between adjacent second heat dissipation assemblies in the plurality of second heat dissipation assemblies form an airflow channel; a gas flows through the plurality of second heat dissipation assemblies by the airflow channel.

11. The computing apparatus according to claim 10, wherein the circuit board is an aluminum substrate.

12. The computing apparatus according to claim 10, wherein the package of each computing unit in the at least one computing unit is provided with a metal plating layer, and each second heat dissipation assembly is welded to the metal plating layer.

13. The computing apparatus according to claim 1, wherein the computing apparatus further comprises a connection element, and the first heat dissipation assembly is detachably connected with the circuit board through the connection element.

14. The computing apparatus according to claim 13, wherein a heat conduction material is filled between the first heat dissipation assembly and the second surface, and the heat conduction material is configured to seal a gap between the first heat dissipation assembly and the circuit board.

15. The computing apparatus according to claim 1, wherein the computing apparatus further comprises a gas inlet assembly and a gas outlet assembly, wherein the gas inlet assembly is arranged at one side of the first heat dissipation assembly and/or the at least one second heat dissipation assembly, and the gas outlet assembly is arranged at the other side of the first heat dissipation assembly and/or the at least one second heat dissipation assembly; wherein the gas inlet assembly is configured to convey a gas to the first heat dissipation assembly and/or the at least one second heat dissipation assembly, and the gas outlet assembly is configured to output the gas that has flowed through the first heat dissipation assembly and/or the at least one second heat dissipation assembly.

16. A heat dissipation apparatus, comprising the first heat dissipation assembly and the at least one second heat dissipation assembly according to claim 1, wherein the first heat dissipation assembly and the at least one second heat dissipation assembly are configured to dissipate heat generated when the at least one computing unit is in operation.
